(19) United States
(12) Patent Application Publication
(10) Pub. No.: US 2015/0092344 A1
(43) Pub. Date: Apr. 2, 2015

(54) PUSH PIN AND GRAPHICS CARD WITH THE PUSH PIN

(71) Applicant: NVIDIA Corporation, Santa Clara, CA (US)

(72) Inventors: Zhenhui Zhu, Shenzhen (CN); Qiang Chen, Shenzhen (CN); Charlie Junde Shu, San Ramon, CA (US)

(21) Appl. No.: 14/503,163

(22) Filed: Sep. 30, 2014

(30) Foreign Application Priority Data
Sep. 30, 2013 (CN) 2013-10461276.5

(51) Int. Cl. H01R 12/70; H05K 1/02; H01R 4/48

(52) U.S. Cl. CPC H01R 12/7076; H01R 4/4872; H05K 1/0203
USPC 361/679.54; 439/162

(57) ABSTRACT

The invention discloses a push pin and a graphics card with the push pin. The push pin comprises a rod, a head, an expansion lock and a first spring. The head is disposed at a first end of the rod and having a radial dimension larger than that of the rod. The expansion lock is disposed at a second end of the rod which is opposite to the first end and having a radial dimension larger than that of the rod, wherein the expansion lock is configured to be elastically contractible when entering a component to be installed in an installing direction, and wherein the installing direction is from the first end to the second end. The first spring made of a conducting material and configured to be installable onto the rod from the second end in a direction opposite to the installing direction.

### CROSS-REFERENCE TO RELATED APPLICATIONS

This application claims priority to Chinese Patent Application No. 201310461276.5, filed on Sep. 30, 2013, which is hereby incorporated by reference in its entirety.

### FIELD OF INVENTION

The present invention relates generally to the field of electricity and more particularly to a push pin and a graphics card with the push pin.

### BACKGROUND

A push pin is often used to secure a heat sink onto a circuit board of a graphics card. The rod of the push pin can pass through the through-holes on the heat sink and the circuit board, and the heat sink and the circuit board are secured together by the head disposed at one end of the rod and the lock disposed at the other end of the rod. The lock is insertable in a single direction. However, considering the elasticity of the lock and the low cost of the push pin, the push pin is usually made of a non-metallic material, such as plastic.

Sometimes the circuit board cannot pass the Electromagnetic Interference (EMI) test. The energy is radiated in a plurality of frequencies during the running of the integrated circuit, and the metal heat sink generates a resonant frequency naturally. If one or more of the plurality of radiated frequencies of the integrated circuit reaches the resonant frequency of the heat sink, the heat sink without being grounded will become a well radiating antenna, in this way, most of the energy is radiated, and it causes the failure of the EMI test.

In order to solve the grounding problem, traditionally, additional metal clips are placed between the heat sink and the circuit board to build a short circuit, or metal screws are used instead of the push pins to secure a suitable heat sink to the circuit board. However, additional metal clips would increase the cost and need additional space, and the extended testing time caused by the repeated debugging delays the time to market (TTM) of the product seriously. Using the metal screws to secure the heat sink not only limits the types of the heat sinks, but also requires grounding pads of about 10 mm to be disposed on the circuit board in advance. Also, it reduces the active area on the circuit board for wiring.

### SUMMARY OF THE INVENTION

Accordingly, there is a need for providing a push pin and a graphics card with the same to address the problem in the prior art.

In order to solve the above-mentioned problems, according to one embodiment of the invention, a push pin is provided. The push pin comprises a rod, a head, an expansion lock and a first spring. The head is disposed at a first end of the rod and having a radial dimension larger than that of the rod. The expansion lock is disposed at a second end of the rod which is opposite to the first end and having a radial dimension larger than that of the rod, wherein the expansion lock is configured to be elastically contractible when entering a component to be installed in an installing direction, and wherein the installing direction is a axial direction from the first end to the second end. The first spring made of a conducting material and configured to be installable onto the rod from the second end in a direction opposite to the installing direction.

Preferably, the push pin further comprises a second spring which is located between the head and the first spring in an installed state.

Preferably, the second spring is configured to be installable onto the rod from the second end in the direction opposite to the installing direction.

Preferably, the first spring is configured to provide a load in a range of 2-5 N, and the second spring is configured to provide a load in a range of 9-18 N.

Preferably, an outer diameter of the second spring is smaller than or equal to an outer diameter of the head.

Preferably, an inner diameter of the first spring is smaller than a maximal radial dimension of the expansion lock.

Preferably, the rod, the head and the expansion lock are formed as an integrated member.

Preferably, the rod, the head and the expansion lock are made of a non-metallic material.

Preferably, the expansion lock has a tapered dimension in the installing direction.

According to another embodiment of the invention, a graphics card is provided. The graphics card comprises a circuit board, a heat sink and any push pin mentioned above. The circuit board is provided with a first installing hole thereon, wherein a ground pad is disposed at the periphery of the first installing hole on an upper surface of the circuit board. The heat sink is disposed above the circuit board and provided with a second installing hole thereon.

Preferably, an outer diameter of the first spring is smaller than or equal to a radial dimension of the ground pad.

The push pin provided by the invention may electrically connect the components to be installed. In the case that the push pin is used to secure the heat sink to the circuit board, the grounding function can be achieved without any additional element. Thus the manufacture cost is reduced, and the Time to Market is shortened. The electrical connection with low impedance, such as 0.2-0.5 ohm, is generated between the heat sink and the circuit board. Also, the structure of the push pin is compact, and thus the active area on the circuit board for wiring is increased, since a larger ground pad is not required on the circuit board.

Advantages and features of the present invention will be described in detail below in connection with the accompanying drawings.

### BRIEF DESCRIPTION OF THE DRAWINGS

In order that the advantages of the invention will be readily understood, a more detailed description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings.

FIG. 1 is a perspective view of a graphics card in accordance with one embodiment of the invention;

FIG. 2 is a front view of a graphics card in accordance with one embodiment of the invention;

FIG. 3 is a sectional view of the graphics card as shown in FIG. 2 taken along line A-A;

FIG. 4 is a perspective view of a push pin in accordance with one preferred embodiment of the invention; and

FIG. 5 is a sectional view of the push pin as shown in FIG. 4 with the first spring and the second spring being removed.

### DETAILED DESCRIPTION

In the following discussion, details are presented so as to provide a more thorough understanding of the present invention. However, the present invention may be implemented without one or more of these details as would he apparent to one of ordinary skill in the art. Certain examples are illustrated without elaborate discussion of technical features that would be within the purview of one of ordinary skill in the art so as to avoid confusion with the present invention.

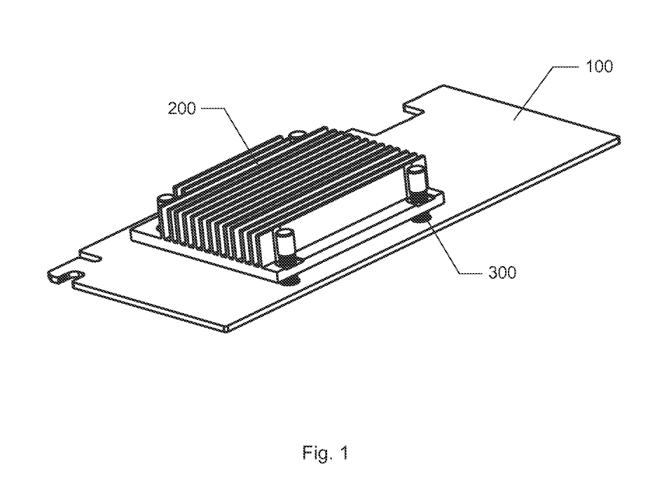

According to one aspect of the invention, a push pin is provided. The push pin is applied to secure a heat sink onto a circuit board of a graphics card, and can ground the heat sink through the circuit board. In order to understand the push pin provided by the invention overall, the graphics card will be simply described by reference to FIGS. 1-3 which has a heat sink, disposed thereon by the push pins.

As shown in FIGS. 1-3, the heat sink 200 is disposed above the circuit board 100 of the graphics card. For the purpose of the heat-dissipation to the circuit board 100, the bottom surface of the heat sink 200 thermally contacts with a main heat-generating component on the circuit board 100. The main heat-generating component basically includes a chip 120 for graphic processing. Preferably, heat-conducting layers may be coated on the contacting surfaces of the heat sink 200 and the circuit board 100 to increase the heat conduction efficiency from the circuit board 100 to the heat sink 200. The heat-conducting layers may be made of a thermal interface material in form of viscous fluid, such as the X23-7762-type thermal interface material provided by the Shin-Etsu MicroSi INC.

FIG. 1 illustrates the heat sink 200 is secured to the circuit board 100 by four push pins 300 at its four corners. However, it is not intended to limit the shape of the heat sink 200, the number of the push pins 300 and the positions of the push pins 300 to those as shown in FIG. 1. In the case that the functions of the push pins 300 described below can be implemented, the push pins 300 may secure the heat sink 200 onto the circuit board 100 in any suitable manner.

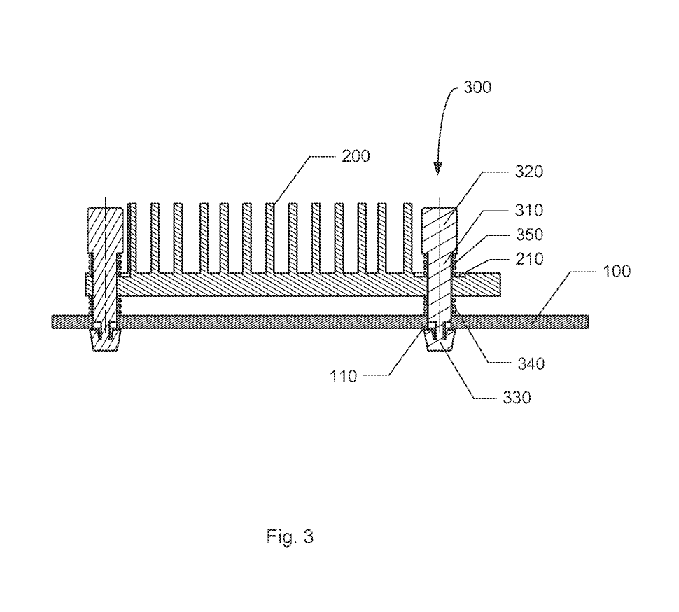

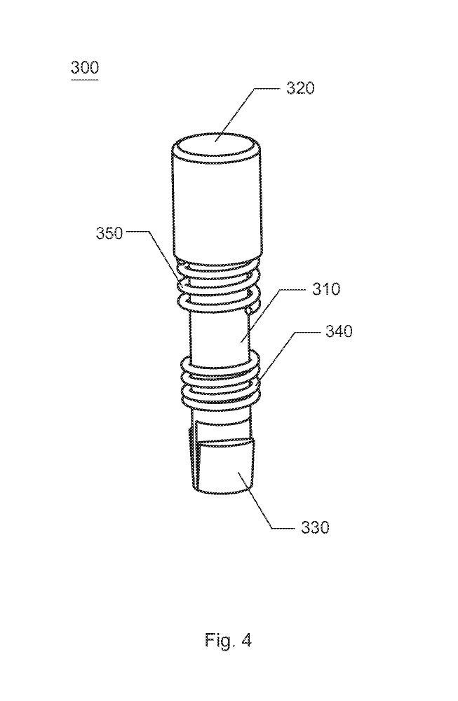

FIG. 4 is a perspective view of the push pin 300 in accordance with one embodiment of the invention. Thus the configuration of the push pin 300 will be described in detail referring to FIG. 4, As shown in FIGS. 3-4, the push pin 300 comprises a rod (e.g. bar) 310, a head 320, an expansion lock 330 and a first spring 340.

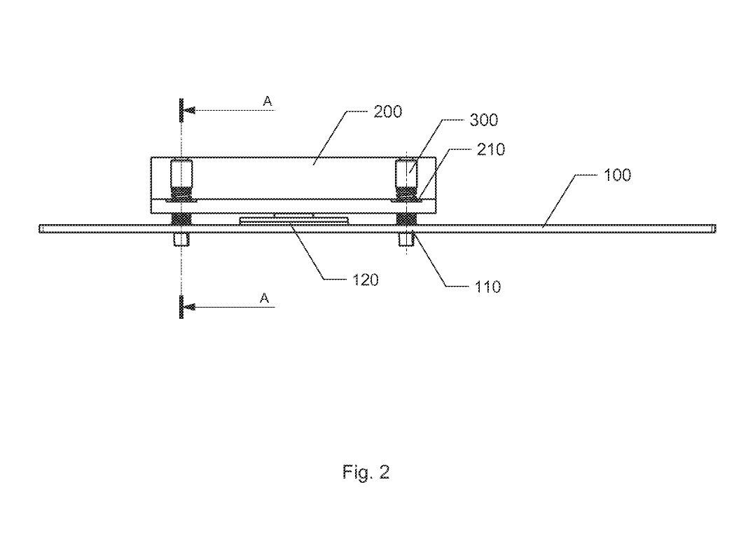

The rod 310 is used to connect the head 320 and the expansion lock 330. During the installation, the rod 310 passes the installing hole on the components to be installed, such as the first installing hole 110 on the circuit board 100 and the second installing hole 210 on the heat sink 200 (see FIGS. 2-3), and the head 320 and the expansion lock 330 clamp the components to be installed therebetween. The components to be installed are not limited to the circuit board and the heat sink. Thus, according to the sizes of the components to be installed and the installing holes thereon, the rod 310 may have different axial lengths and radial dimensions.

The head 320 is disposed at the first end of the rod 310, for example, the upper end as shown in FIG. 4. The expansion lock 330 is disposed at the second end of the rod 310 which is opposite to the first end, for example, the lower end as shown in FIG. 4. Both the head 320 and the expansion lock 330 have radial dimensions larger than the radial dimension of the rod 310. The shape and the configuration of the head 320 are not limited to the embodiment as shown in FIG. 4. The head 320 may have any structure which can block the components to be installed which have been passed through by the rod 310.

The expansion lock 330 is configured to be elastically contractible when entering a component to be installed in an installing direction. The installing direction is the axial direction from the first end to the second end of the rod 310, corresponding to the direction from top to bottom as shown in FIG. 4. When the push pin 300 is installed to the component to be installed, the push pin 300 is pressed at the head 320 in the downward direction and its expansion lock 330 first enters the component to be installed. The expansion lock 330 can be contracted elastically when entering the component to be installed in the installing direction, such that the expansion lock 330 can pass through the installing hole on the component to be installed smoothly. After passing through the installing hole, the expansion lock 330 gets back its original shape due to its elasticity. In this way, the component to be installed is clamped between the head 320 and the expansion lock 330. Nevertheless, when the push pin 300 is moved in the direction opposite to the installing direction, the expansion lock 330 cannot be contracted elastically. The component clamped between the head 320 and the expansion lock 330 cannot be removed from the push pin 300.

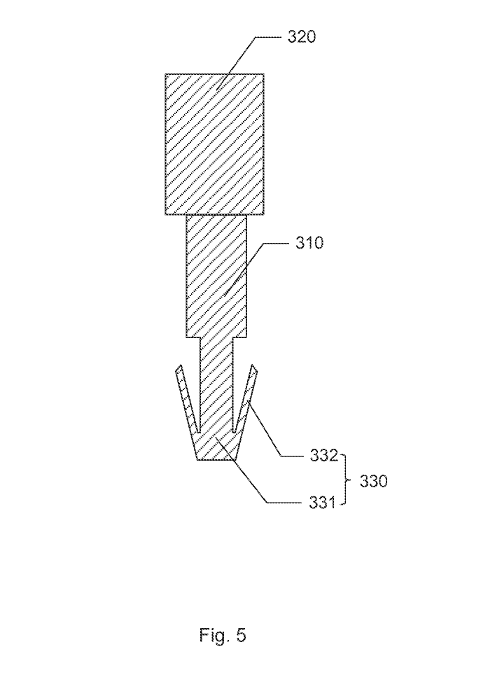

In one preferred embodiment, as shown in FIG. 5, the expansion lock 330 may include a body 331 and a plurality of expansions 332. The upper end of the body 331 is connected to the second end of the rod 310. The plurality of expansions 332 are connected to the lower portion of the body 331, and the plurality of expansions 332 are inclined upwardly. The plurality of expansions 332 can have such dimensions that they have elasticity. When the push pin 300 enters the component to be installed in the installing direction, the plurality of expansions 332 become closer to the body 331 such that the expansion lock 330 passes through the installing hole smoothly. As the push pin 300 is moved in the direction opposite to the installing direction, the plurality of expansions 332 can act as the stoppers.

Returning to FIG. 4, although the first spring 340 has been mounted onto the rod 310 in FIG. 4, actually, before the push pin 300 is installed to the component to be installed, the first spring 340 is separated from the rod 310. In the installed state, as shown in FIGS. 1-3, the first spring 340 surrounds the rod 310 and is positioned between the heat sink 200 and the circuit board 300. The first spring 340 is configured to be installable onto the rod 310 from the second end in a direction opposite to the installing direction. When installing the first spring 340, the expansion lock 330 is contracted elastically due to the pressure of the spring. Taking the embodiment shown in FIG. 3 as an example, the push pin without the first spring 340 thereon is first installed to the second installing hole 210 of the heat sink 200 in the installing direction. After the expansion lock 330 passes through the second installing hole 210, the first spring 340 is mounted onto the rod 310. Finally, the first installing hole 110 on the circuit board 100 is aligned with the push pin 300, and the push pin 300 is pressed in the installing direction such that the expansion lock 330 passes through the first installing hole 110.

In one preferred embodiment, the inner diameter of the first spring 340 is smaller than a maximal radial dimension of the expansion lock 330. During the installation of the first spring 340, the expansion lock 330 is contracted elastically. Once the first spring 340 is mounted on the rod 310, it cannot be separated from the rod 310 easily. In this way, the convenience of installation may be improved when the push pin 300 is used to install the components to be installed.

In another preferred embodiment, the expansion lock 330 has a tapered dimension in the installing direction, as shown in FIG. 5. Thus, the push pin 300 can easily enter the installing holes on the components to be installed.

Also, the first spring 340 is made of a conducting material. On the upper surface of the circuit board 100, a ground pad (not shown) is disposed at the periphery of the first installing hole 110. The heat sink 200 is disposed above the circuit board 100. In the installed state as shown in FIG. 3, the ground pads on the lower surface of the heat sink 200 and on the upper surface of the circuit board 100 electrically contact with the spring. The heat sink 200 can be grounded by the ground pads. It may avoid the failure of the EMI test.

The “upper surface” and “lower surface” of the circuit board mentioned herein are relative. When the placements of the circuit board 100 and the heat sink 200 are reversed, the “upper surface” mentioned above changes to the lower surface located below, and the “lower surface” mentioned above changes to the upper surface located above.

Preferably, the outer diameter of the first spring 340 is smaller than or equal to a radial dimension of the ground pad, to prevent the first spring 340 from destroying the wiring on the circuit board 100 during the installation.

Preferably, the rod 310, the head 320 and the expansion lock 330 are integrated with each other, for example by way of moulding, to form an integrated member. Preferably, the rod 310, the head 320 and the expansion lock 330 are made of a non-metallic material, to facilitate the manufacture and reduce the cost.

The push pin provided by the invention may electrically connect the components to be installed, in the case that the push pin is used to secure the heat sink to the circuit board, the grounding function can be achieved without any additional element. Thus the manufacture cost is reduced, and the Time to Market is shortened. The electrical connection with low impedance, such as 0.2-0.5 ohm, is generated between the heat sink and the circuit board. Also, the structure of the push pin is compact, and thus the active area on the circuit board for wiring is increased, since a larger ground pad is not required on the circuit board.

In a further preferred embodiment, the push pin 300 also comprises a second spring 350, as shown in FIGS. 2-4. As best shown in FIG. 4, the second spring 350 is located between the head 320 and the first spring 340 in the installed state. Further, as best shown in FIG. 3, in the installed state that the push pin 300 is installed to the components to be installed, the second spring is located between the components to be installed and the head 320. The components to be installed, such as the heat sink 200 and the circuit board 100, are all under the protection of the elastic buffer force. Thus, the circuit board 100 can be prevented from being damaged by the shake and collision during the transportation and processing. Moreover, the elements on the circuit board 100 may be prevented in the test of mechanical shock. In one embodiment, the second spring 350 may be secured to the head 320 or the first end of the rod 310 between the head 320 and the expansion lock 330. The second spring 350 may be secured to the head 320 or the first end of the rod 310 in any known way. in another embodiment, the second spring 350 may be not secured to the head 320 or the rod 310, so that the manufacture of the push pin 300 is simplified. Further preferably, the second spring 350 may be similar to the first spring 340. It can be configured to be installable onto the rod 310 from the second end in the direction opposite to the installing direction. That is, the second spring 350 may installed onto the rod 310 as needed, such as when the push pin 300 is installed to the components to be installed. It extends the application of the push pin 300. When the second spring 350 is installed onto the rod 310, the expansion lock is contracted elastically. In this preferred embodiment, before the installation steps mentioned above, the second spring 350 is firstly installed onto the rod 310. Moreover, the inner diameter of the second spring 350 is smaller than the outer diameter of the head 320, such that the second spring 350 cannot be removed from the head 320.

Further preferably, the first spring 340 is configured to provide a load in the range of 2-5 N, and the second spring 350 is configured to provide a load in the range of 9-18 N. When the heat sink 200 is secured to the circuit board 100 by the push pin 300, the first spring 340 and the second spring 350 may keep the circuit board 100 and heat sink 200 secure.

In addition, the outer diameter of the second spring 350 is smaller than or equal to the outer diameter of the head 320. In this way, the overall size of the push pin 300 can be prescribed according to the size of the head 320. And, the push pin 300 can be covered by the head 320 after installation, which ensures a smooth surface of the installing position.

It is appreciated that both the first spring 340 and the second spring 350 are preferably in compressed states, when the push pin 300 is in the installed state. Otherwise, neither the first spring 340 nor the second spring 350 can act as a protection. Thus based on the sizes of the components to be installed and the distance between the head 320 and the expansion lock 330, the lengths of the first spring 340 and the second spring 350 can be selected suitably.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as may be suited to the particular use contemplated.

Embodiments according to the invention are thus described. While the present disclosure has been described in particular embodiments, it should be appreciated that the invention should not be construed as limited by such embodiments, but rather construed according to the below claims.

What is claimed is:

1. A push pin, comprising:
a rod;
a head disposed at a first end of the rod and having a radial dimension larger than that of the rod;
an expansion lock disposed at a second end of the rod which is opposite to the first end and having a radial dimension larger than that of the rod, wherein the expansion lock is configured to be elastically contractible when entering a component to be installed in an installing direction, and wherein the installing direction is a axial direction from the first end to the second end; and
a first spring made of a conducting material and configured to be installable onto the rod from the second end in a direction opposite to the installing direction.

2. The push pin according to claim 1, wherein the push pin further comprises a second spring which is located between the head and the first spring in an installed state.

3. The push pin according to claim 2, wherein the second spring is configured to be installable onto the rod from the second end in the direction opposite to the installing direction.

4. The push pin according to claim 2, wherein the first spring is configured to provide a load in a range of 2-5 N, and the second spring is configured to provide a load in a range of 9-18 N.

5. The push pin according to claim 2, wherein an outer diameter of the second spring is smaller than or equal to an outer diameter of the head.

6. The push pin according to claim 1, wherein an inner diameter of the first spring is smaller than a maximal radial dimension of the expansion lock.

7. The push pin according to claim 1, wherein the rod, the head and the expansion lock are formed as an integrated member.

8. The push pin according to claim 1, wherein the rod, the head and the expansion lock are made of a non-metallic material.

9. The push pin according to claim 1, wherein the expansion lock has a tapered dimension in the installing direction.

10. A graphics card, comprising:
a circuit board provided with a first installing hole thereon, wherein a ground pad is disposed at the periphery of the first installing hole on an upper surface of the circuit board;
a heat sink disposed above the circuit board and provided with a second installing hole thereon; and
a push pin, comprising:
a rod;
a head disposed at a first end of the rod and having a radial dimension larger than that of the rod;
an expansion lock disposed at a second end of the rod which is opposite to the first end and having a radial dimension larger than that of the rod, wherein the expansion lock is configured to be elastically contractible when entering a component to be installed in an installing direction, and wherein the installing direction is a axial direction from the first end to the second end; and
a first spring made of a conducting material and configured to be installable onto the rod from the second end in a direction opposite to the installing direction,
wherein the expansion lock passes through the first installing hole and the second installing hole to install the heat sink to the circuit board, and wherein the first spring is disposed between the heat sink and the circuit board and electrically contacts with the heat sink and the ground pad.

11. The graphics card according to claim 10, wherein the push pin further comprises a second spring which is located between the head and the first spring.

12. The graphics card according to claim 11, wherein the second spring is configured to be installable onto the rod from the second end in the direction opposite to the installing direction.

13. The graphics card according to claim 11, wherein the first spring is configured to provide a load in a range of 2-5 N, and the second spring is configured to provide a load in a range of 9-18 N.

14. The graphics card according to claim 11, wherein an outer diameter of the second spring is smaller than or equal to an outer diameter of the head.

15. The graphics card according to claim 10, wherein an inner diameter of the t spring is smaller than a maximal radial dimension of the expansion lock.

16. The graphics card according to claim 10, wherein the rod, the head and the expansion lock are formed as an integrated member.

17. The graphics card according to claim 10, wherein the rod, the head and the expansion lock are made of a non-metallic material.

18. The graphics card according to claim 10, wherein the expansion lock has a tapered dimension in the installing direction.

19. The graphics card according to claim 10, wherein an outer diameter of the first spring is smaller than or equal to a radial dimension of the ground pad.
